(19) United States
(12) Patent Application Publication
(10) Pub. No.: US 2015/0237722 A1
(43) Pub. Date: Aug. 20, 2015

(54) Anode Array

(71) Applicants: Ruey-Jen Hwu, Salt Lake City, UT (US); Jishi Ren, Ottawa Ontario (CA); Laurence P. Sadwick, Salt Lake City, UT (US)

(72) Inventors: Ruey-Jen Hwu, Salt Lake City, UT (US); Jishi Ren, Ottawa Ontario (CA); Laurence P. Sadwick, Salt Lake City, UT (US)

(21) Appl. No.: 14/628,189

(22) Filed: Feb. 20, 2015

Related U.S. Application Data
(60) Provisional application No. 61/942,528, filed on Feb. 20, 2014.

(51) Int. Cl. H05K 1/02; H01R 43/20

(52) U.S. Cl. CPC H05K 1/0296; H05K 1/0284; H01R 43/205; H05K 2201/0332

(57) ABSTRACT

An anode array system includes a number of electrically conductive strips arranged in an array to form an anode, each of the plurality of electrically conductive strips having a first end and a second end, electrical connectors at the first end and at the second end of each of the electrically conductive strips, and a substrate at least partially supporting the electrically conductive strips, wherein the substrate is porous.

### BACKGROUND

A microstrip anode is an anode structure having an array of electrically conductive strips or lines. A corresponding cathode can be positioned next to the microstrip anode, with a substrate between the microstrip anode and the cathode. Connectors such as coaxial connectors can be connected to the ends of the anode strips and to the cathode. As such devices are used for increasingly high speed applications, the signal propagation speed along the anode strips and the bandwidth transmission become limiting characteristics of increasing importance. A lower speed of a wave traveling through the anode strips results in a shorter wavelength for the same frequency range and increases electrical length. This increases coupling among strips and loss of transmission, all of which will be translated to a rapid transmission drop when frequency increases.

### BRIEF SUMMARY

Some embodiments of the present invention provide a microstrip anode device with a substrate having a lower overall dielectric constant, by selectively removing or omitting material from the substrate. In some embodiments, some substrate material is removed from an underside, opposite the microstrip anode. In some embodiments, slits, grooves or channels are cut in the substrate. Such grooves or channels can be under or between the strips or placed in another arrangement. In some embodiments, a honeycomb pattern of tubes or other structures is formed in the substrate. In some embodiments, material is removed from the substrate, leaving supportive posts or pillars to support the cathode. In some embodiments, material is selectively added via an additive process to create, for example, posts and/or pillars, etc.

Notably, the substrate formation to result in a lower overall dielectric constant is not limited to any particular process or operation, and the use of the term “removed” does not specify or imply that a solid substrate is first provided then modified. Rather, the non-solid substrate can be formed in any suitable manner, such as a formation process that selectively places or deposits material where desired in the substrate, or in a combination of additive and subtractive operations.

This summary provides only a general outline of some embodiments according to the present invention. Many other embodiments of the present invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals are used throughout several figures to refer to similar components.

FIG. 1 depicts a top view of a microstrip anode in accordance with some embodiments of the present invention;

FIG. 2 depicts a side view of a microstrip anode, substrate and cathode along a cross-section through an anode strip and showing only solid substrate in accordance with some embodiments of the present invention;

FIG. 3 depicts a side view of a microstrip anode, substrate and cathode along a cross-section through an anode strip and showing cavities in the substrate in accordance with some embodiments of the present invention;

FIG. 4 depicts an end view of a microstrip anode, substrate and cathode showing cavities in the substrate under anode strips in accordance with some embodiments of the present invention;

FIG. 5 depicts an end view of a microstrip anode, substrate and cathode showing cavities in the substrate between anode strips in accordance with some embodiments of the present invention;

FIG. 6 depicts an end view of a microstrip anode, substrate and cathode showing cavities in the substrate under anode strips and extending into spaces between the anode strips in accordance with some embodiments of the present invention; and

FIG. 7 depicts an end view of a microstrip anode, substrate and cathode showing cavities in the substrate between anode strips and extending into spaces under the anode strips in accordance with some embodiments of the present invention.

### DETAILED DESCRIPTION OF THE INVENTION

Embodiments of the present invention are related to a microstrip anode device with a substrate between the microstrip anode and a cathode having a reduced (effective) dielectric constant when compared with a solid substrate of the same material, by selectively removing or omitting material from the substrate. In some embodiments, substrate material is removed from an underside, opposite the microstrip anode. In other embodiments the substrate is removed from the topside/upper side, etc. In some embodiments, grooves, slits, spacers, tubes or channels, etc. are cut in the substrate. Such grooves or channels can be under or between the strips or placed in another arrangement. In some embodiments, a honeycomb pattern or honeycomb-like pattern is formed in the substrate. In some embodiments, material is removed from the substrate, leaving supportive posts or pillars to support the cathode. The substrate is thus porous, where the term “porous” indicates that the substrate is not a homogenous solid material, but contains voids or regions which are not formed from the same material as the substrate frame. These voids or regions can be filled with any material in any state, including, but not limited to, air or other materials in gaseous, liquid or solid state, and can also be evacuated to form a vacuum.

Notably, the substrate formation to result in a lower overall dielectric constant is not limited to any particular process or operation, and the use of the term “removed” does not specify or imply that a solid substrate is first provided then modified. Rather, the non-solid substrate can be formed in any suitable manner, such as a formation process that selectively places or deposits material where desired in the substrate, or in a combination of additive and subtractive operations.

The microstrip anode device disclosed herein is not limited to use with any particular application. In some embodiments, the microstrip anode device is used in a very fast large-area photodetector with picosecond-level resolution for providing better time, energy, position, etc.

resolutions. Radio frequency or RF-strip-line anodes for large-area microchannel plate (MCP)-based photodetectors provide for the foundation of fast photodetectors. MCP-based photodetectors offer the small intrinsic spatial scale necessary for small fluctuations in timing due to path length variations, but, at the same time, are scalable to large areas. Microstrip anodes as disclosed herein, also referred to as RF transmission line anodes or large-area picosecond photo-detectors (LAPPD) anode arrays in some embodiments, can cover large areas inexpensively while preserving the time resolution method of digitizing the signal. Microstrip anodes can be daisy chained in series to cover more area with the same electronics channel count. The microstrip anode disclosed herein can achieve picosecond and sub-picosecond time resolution, and can be used in MCP-based detectors with analog bandwidths in the multi-GHz, while maintaining the large area of the photodetector for better signal-to-noise performance. In some embodiments, the substrate is a sealable glass substrate.

Other applications for some embodiments of the microstrip anode include less expensive, lower cost, and more precise Positron Emission Tomography (PET) cameras in medical imaging, scanners for transportation security, and particle detectors in high-energy neutrino and collider physics, astrophysics, and nuclear physics. Photodetection anodes can be optimized for neutron or photon detection. Large area panels would allow economical scanners for containers and trucks in nuclear non-proliferation and transportation security, respectively.

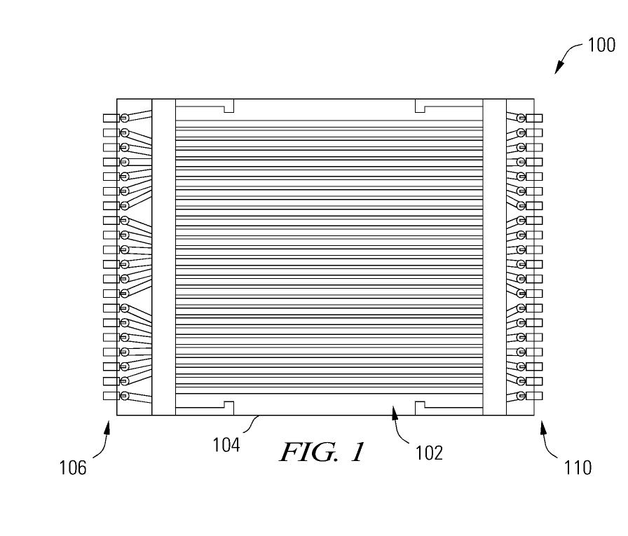

Turning to FIG. 1, a top view of a microstrip anode 100 is shown in accordance with some embodiments of the present invention. The microstrip anode 100 is not limited to any particular number of anode strips, or to any particular width, length, or spacing of the anode strips. Although the anode strips are shown as straight conductors in parallel configuration with uniform widths, the microstrip anode is not limited to this configuration, and anode strips can be positioned at angles to each other, can have varying widths, can change directions, curve, etc. An array of anode strips 102 is positioned on a substrate 104, running between sets of connectors 106, 110. In this view, a cathode (not shown) lies beneath the substrate 104. The anode strips 102 can be formed directly on the substrate 104, or be provided in another manner and placed against substrate 104. For example, in some embodiments, the anode strips are formed directly on the substrate between the anode strips and cathode, such as by deposition of a metal layer on a glass substrate 104, followed by patterning including, for example, but not limited to, photolithography and etching to remove undesired metal material to leave the anode strips 102. Any method may be used to pattern, form, create, remove, cut, add, subtract, etc. to produce the anode strips and associated structures. In some other embodiments, the anode strips 102 are formed on another substrate and then positioned against a separate dielectric substrate 104 between the anode strips 102 and a cathode below, such that the substrate on which the anode strips 102 are formed is not between the anode strips 102 and cathode. The anode plate can also be free standing, formed on a thin dielectric as mentioned above, deposited on another material, etc.

The anode strips 102, substrate 104 and cathode can be formed using any suitable materials giving the desired behavioral characteristics, such as a copper material, a copper alloy, silver, silver paste, and in certain cases, gold, platinum, aluminum, etc. or, in general, other electrically conductive material for the anode strips 102, and a glass or other material with a suitable dielectric constant for the substrate 104. In some embodiments, the substrate 104 is a borofloat glass with removed or omitted sections. Although the microstrip anode is not limited to any particular layout or configuration of slits, grooves, tubes, channels, cavities, etc. in the substrate, in one example embodiment with a honeycomb substrate structure containing a 65% open air ratio, the signal transit time across the anode strips is reduced by about 35% as compared with a solid substrate structure.

Methods such as sputtering, thermal evaporation, electron beam evaporation, plasma evaporation, plasma assisted evaporation, molecular beam epitaxy or evaporation, and other physical vapor deposition, chemical vapor deposition, etc, electroplating, electroless plating, etc,

Embodiments of the present invention can also use mechanical and machining approaches to realize implementations, of the present invention including molding, punching, forming, 3-D (three dimensional) printing, cutting, pressing, lathing, sawing, water jetting, etc.

Electrical signals can be connected to the anode strips 102 and cathode in any suitable manner, such as, but not limited to, using a coaxial SMA connector, or Sub-Miniature version A coaxial RF connectors, with the center conductors connected to the anode strips 102 and the outer sleeve conductors connected to the cathode.

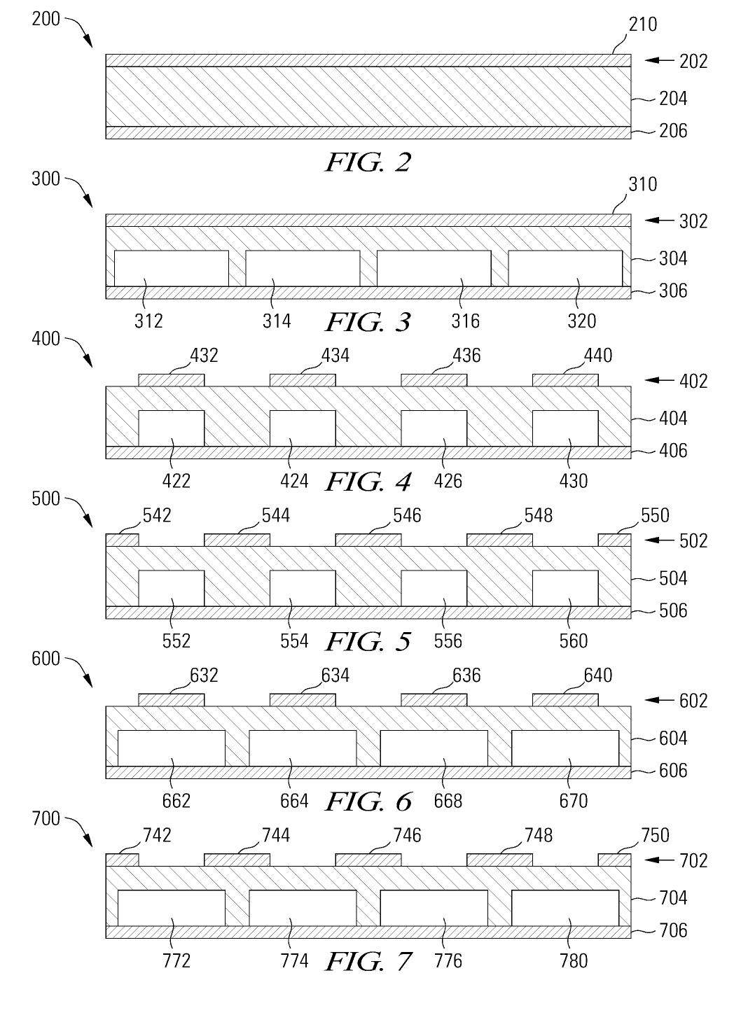

Turning to FIG. 2, a side view of a microstrip device 200 depicts a microstrip anode 202, substrate 204 and cathode 206 along a cross-section through an anode strip 210 and showing only a solid cross-section of the substrate 204 in accordance with some embodiments of the present invention. The substrate 204 includes cavities (not shown), missing material, or openings of any configuration, causing the substrate 204 to have an overall dielectric constant such that the microstrip device 200 has the desired signal transmission frequency, bandwidth and other characteristics. The microstrip device 200 is not limited to any particular configuration, including the relative thicknesses of the microstrip anode 202, substrate 204 and cathode 206. The drawing in FIG. 2 is merely a non-limiting example. The details and measurements of the elements of the microstrip device 200 can be configured in any manner to provide the desired operating characteristics.

Turning to FIG. 3, a side view of a microstrip device 300 depicts a microstrip anode 302, substrate 304 and cathode 306 along a cross-section through an anode strip 310 and showing cavities 312, 314, 316, 320 in the substrate 304 in accordance with some embodiments of the present invention. The microstrip device 300 may extend to the left and right beyond the edges of drawing in FIG. 3, with connectors at the left and right end of the anodes 302. The microstrip device 300 is not limited to any particular number of cavities 312, 314, 316, 320. The cavities 312, 314, 316, 320 may be interconnected to form one large cavity, or may be independent and separate from each other. In some embodiments, the cavities 312, 314, 316, 320 are filled with air. In some other embodiments, the cavities 312, 314, 316, 320 are filled with another gas. In some other embodiments, the cavities 312, 314, 316, 320 are pumped down to a vacuum, including a high vacuum or ultra-high vacuum, or partial vacuum.

Turning to FIG. 4, an end view of a microstrip device 400 depicts a microstrip anode 402, substrate 404 and cathode 406 showing cavities 422, 424, 426, 430 in the substrate 404 under the anode strips 432, 434, 436, 440 in accordance with some embodiments of the present invention. In this embodiment, the cavities 422, 424, 426, 430 are substantially the same width as the anode strips 432, 434, 436, 440 and lie under the anode strips 432, 434, 436, 440. The cavities 422, 424, 426, 430 may run the entire length of the anode strips 432, 434, 436, 440 or may comprise a number of separate cavities 422, 424, 426, 430.

Turning to FIG. 5, an end view of a microstrip device 500 depicts a microstrip anode 502, substrate 504 and cathode 506 showing cavities 552, 554, 556, 560 in the substrate 504 between the anode strips 542, 544, 546, 548, 550 in accordance with some embodiments of the present invention. In this embodiment, the cavities 552, 554, 556, 560 are substantially the same width as the gaps between anode strips 542, 544, 546, 548, 550 and lie between the anode strips 542, 544, 546, 548, 550. The cavities 552, 554, 556, 560 may run the entire length of the anode strips 542, 544, 546, 548, 550 or may comprise a number of separate cavities 552, 554, 556, 560.

Turning to FIG. 6, an end view of a microstrip device 600 depicts a microstrip anode 602, substrate 604 and cathode 606 showing cavities 662, 664, 668, 670 in the substrate 604 under anode strips 632, 634, 636, 640 and extending into spaces between the anode strips 632, 634, 636, 640 in accordance with some embodiments of the present invention. The amount by which the cavities 662, 664, 668, 670 in the substrate 604 extend beyond the anode strips 632, 634, 636, 640 is not limited to the distance shown in the example of FIG. 6. The depth of the cavities 662, 664, 668, 670 in the substrate 604 is also not limited to that shown. The size and shape of the cavities 662, 664, 668, 670 can be adapted to balance the stability and rigidity of the substrate 604 to provide the desired support to microstrip anode 602 and cathode 606, versus the desired dielectric constant of the substrate 604. The size and shape of the cavities 662, 664, 668, 670 can also be adapted to achieve the desired electrical and/or magnetic field effects during operation of the microstrip device 600.

Turning to FIG. 7, an end view of a microstrip device 700 depicts microstrip anode 702, substrate 704 and cathode 706 showing cavities 772, 774, 776, 780 in the substrate 704 between anode strips 742, 744, 746, 748, 750 and extending into spaces under the anode strips 742, 744, 746, 748, 750 in accordance with some embodiments of the present invention. The amount by which the cavities 772, 774, 776, 780 in the substrate 704 undercut the anode strips 742, 744, 746, 748, 750 is not limited to the distance shown in the example of FIG. 7. The depth of the cavities 762, 764, 768, 770 in the substrate 704 is also not limited to that shown. The size and shape of the cavities 762, 764, 768, 770 can be adapted to balance the stability and rigidity of the substrate 704 to provide the desired support to microstrip anode 702 and cathode 706, versus the desired dielectric constant of the substrate 704. The size and shape of the cavities 762, 764, 768, 770 can also be adapted to achieve the desired electrical and/or magnetic field effects during operation of the microstrip device 700.

Although FIGS. 2 through 7 generally show the cavities as being below the anode with solid material directly below the anode, this is merely for illustrative purposes and the cavities could also be directly below or in any other configuration including both directly below and partially below the anode etc. It is understood that words indicating vertical relative positions such as below, directly below, above, etc. are merely intended to be illustrative for the particular drawings of the present invention and not limiting in any way or form.

Again, material can be removed or omitted from the substrate between the microstrip anode and the cathode in any manner and pattern. In some embodiments, the substrate includes cavities on the side opposite the microstrip anode and adjacent the cathode, although the microstrip anode device is not limited to this configuration. The cavities may have any height in the substrate and any suitable layout. In some embodiments, the cavities comprise circular cutouts, as in a honeycomb patterned cavity pattern. In some embodiments, the cavities comprise slits, grooves, tubular openings/channels, square openings/channels, rectangular openings/channels, oblong openings/channels, etc. or slots in any width, depth, orientation, spacing, etc. In some embodiments, the cavities comprise a single large cavity with supportive posts or pillars throughout the cavity to provide support to the anode and/or cathode. In some embodiments the cavities may, but are not limited to, have one or more of the following shapes: square, circular, elliptical, round, hexagonal, octagonal, star, triangular, rectangular, N-sided where N is typically greater than 3, oblong, elongated, tubes, cylinders, parallel-piped, spheres, semi-circles, semi-spheres, arbitrary, etc.

Although the figures have in general illustrated a vertical type of cavity structure, horizontal and lateral cavity structures that, for example, run parallel or perpendicular to the plane of the anodes may also be used. In general any type of vertical, horizontal, lateral cavities and cavity structures, types, forms, geometries, construction, design, fabrication, assembly, manufacturing, etc. or combinations of these may be used to realize and implement the present invention.

The substrate for the microstrip anode device can be manufactured or fabricated in any suitable manner. In some embodiments, the substrate is manufactured by providing a solid substrate and fabricating walls on the solid substrate to result in a substrate with cavities defined by the walls. Such walls may be formed by a combination of additive and subtractive operations. For example, pattern material such as photoresist can be deposited in the locations of the walls, followed by deposition of sacrificial material to fill in the cavity locations between the wall locations. The pattern material in the locations can then be removed or etched away. A wall material can then be deposited in the wall locations where the pattern material was removed, followed by removal or etching of the sacrificial material filling the cavity locations, resulting in walls with cavities between them. Thus, pillars and/or posts could use (i.e., be formed by) additive or subtractive methods, including, but not limited to, etching (chemical, dry or plasma, etc, or combinations), molds, photoresist including SU-8 and other photoresists including, but not limited to screen printable photoresists and other materials and such materials, blanket photomaterials and photoresists, fusing, bonding, heat treatment, water jetting, sawing, dicing, molding, 3-D printing, precision machining, conventional machining, casting, micromachining, microfabrication, nanofabrication, fixtures, fixturing, melting, ablation including laser ablation, plasma jetting, plasma deposition, PVD, CVD, ALE, ALD, stamping, printing, pressing, frit, frit molding, heat treatment, light sensitive materials, etc.

Materials including hollow or otherwise tubes, balls, cylinders, squares, rectangles, most any geometrical shapes and individual components etc. to realize and implement a reduced material volume, surface area and/or area structure with an effective lower dielectric constant.

Most any periodic/symmetric cavity and support structure can be used, to provide the desired overall or averaged effective dielectric constant without substantially affecting the field and mode distribution of the microstrip anodes. Cross members, four squares, ‘open air’ structures, diamonds, squares, circles, frames with cut-outs, arrays of pillars and/or posts, cut-outs, bottom openings, etc. can be used.

In conclusion, embodiments of the present invention provide novel systems, devices, methods and arrangements for a high speed microstrip anode. While detailed descriptions of one or more embodiments of the invention have been given above, various alternatives, modifications, and equivalents will be apparent to those skilled in the art without varying from the spirit of the invention. Therefore, the above description should not be taken as limiting the scope of embodiments of the invention which are encompassed by the appended claims.

What is claimed is:

1. An apparatus comprising:
a plurality of electrically conductive strips arranged in an array to form an anode, each of the plurality of electrically conductive strips having a first end and a second end;
electrical connectors at the first end and at the second end of each of the plurality of electrically conductive strips; and
a substrate at least partially supporting the plurality of electrically conductive strips, wherein the substrate is porous.

2. The apparatus of claim 1, wherein the substrate has a lower overall dielectric constant than a solid substrate would have being formed of a same material.

3. The apparatus of claim 1, wherein the porous substrate is formed by removing material from a solid structure.

4. The apparatus of claim 1, wherein the porous substrate comprises a plurality of pillars supporting the plurality of electrically conductive strips.

5. The apparatus of claim 1, wherein the porous substrate comprises at least one void formed in a side opposite the plurality of electrically conductive strips.

6. A method of fabricating a microstrip anode, comprising:
providing a solid substrate comprising a material with a first dielectric constant;
placing a plurality of electrically conductive strips on the solid substrate;
removing at least one portion of the solid substrate to yield a porous substrate having a second overall dielectric constant, wherein the second overall dielectric constant is lower than the first dielectric constant; and
mounting electrical connectors at ends of each of the plurality of electrically conductive strips.

7. The method of claim 6, wherein removing at least one portion of the solid substrate to yield a porous substrate comprises removing the at least one portion of the solid substrate from a side of the solid substrate opposite a mounting side for the plurality of electrically conductive strips.

8. A method of fabricating a microstrip anode, comprising:
forming a porous substrate from a material with a dielectric constant, wherein the porous substrate has at least one void not containing the material with the first dielectric constant, wherein an overall dielectric constant of the porous substrate is lower than the dielectric constant of the material;
placing a plurality of electrically conductive strips on the porous substrate; and
mounting electrical connectors at ends of each of the plurality of electrically conductive strips.

9. The method of claim 8, wherein the porous substrate is formed by removing at least one portion from a solid substrate.

10. The method of claim 9, wherein the plurality of electrically conductive strips are placed on the porous substrate after removing the at least one portion from the solid substrate.

11. The method of claim 9, wherein the plurality of electrically conductive strips are placed on the solid substrate before removing the at least one portion from the solid substrate to yield the porous substrate.

12. The method of claim 8, wherein the porous substrate is formed by depositing the material in a non-uniform manner that leaves the at least one void without the material.
